(19) United States
(12) Patent Application Publication
(10) Pub. No.: US 2023/0290855 A1
(43) Pub. Date: Sep. 14, 2023

(54) TRANSISTOR STRUCTURE HAVING AN AIR SPACER AND METHOD FOR MAKING THE SAME

(71) Applicant: HeFeChip Corporation Limited, Hong Kong (HK)

(72) Inventors: John H Zhang, Altamont, NY (US); Chun Yu Wong, Hong Kong (HK); Sunil K Singh, Mechanicville, NY (US); Liang Li, Singapore (SG); Heng Yang, Rexford, NY (US)

(21) Appl. No.: 17/654,422

(22) Filed: Mar. 11, 2022

(51) Int. Cl. H01L 29/51; H01L 29/66

(52) U.S. Cl. CPC H01L 29/515; H01L 29/6653

(57) ABSTRACT

The invention discloses a transistor structure including a substrate, a semiconductor layer disposed on the substrate and a gate layer disposed on the semiconductor layer, wherein the gate layer includes at least one gate having a first height, a first side and a second side opposite to the first side, a first dielectric spacer is disposed at the first side of the at least one gate, a first air spacer having a second height is disposed inside the first dielectric spacer, and the second height is lower than the first height.

### FIELD OF THE INVENTION

The present invention is related to a semiconductor device with a transistor structure, in particular a transistor structure having an air spacer and the method for making the same.

### BACKGROUND OF THE INVENTION

A typical transistor is composed of a source, a drain and a gate configured to control whether the path from the drain to the source is an open circuit (off) or a resistive path (on). In semiconductor technology, for realizing a single transistor, the source and the drain are often made of two different doped regions in the same layer of a silicon wafer while the gate is disposed on top and between the source and the drain. Both sides of the gate are often configured with spacers formed of dielectric or high-k material for insulation between the source or drain contact and the gate.

As the dimensions of the transistor structure continue to shrink, following the semiconductor technology trend, due to the existence of high dielectric constant of the dielectric materials such as silicon nitride or silicon oxide disposed between the two metal elements in parallel, parasitic capacitance may occur between the gate and the drain and/or the source contacts, which results in high RC delay for the circuit. To lower the parasitic capacitance effect to the circuit, air-gap spacers can be employed to replace a portion of the dielectric material of the dielectric spacer.

In U.S. Pat. No. 9,911,652B1, a method of forming self-aligned vias and air gaps in semiconductor fabrication is introduced. However, such a method is not applicable to the formation of air gaps for transistors.

In U.S. Pat. No. 9,362,355B1, a transistor device with full-height air-gap spacers disposed at two sides of the gate is introduced, wherein the air gaps are formed by selective etching and refilling, in which the shape and the size of the air spacers cannot be in good control so there may result in a variation of the transistor performance.

In U.S. Pat. No. 10,923,389B1, structures for a field-effect transistor that include an air-gap spacer and methods for forming the same are introduced. Likewise, the air gaps are formed by selective etching and refilling, and thus the shape and the size of the air spacers cannot be well in control.

In U.S. Pat. No. 10,211,092B1, air gaps are formed in fin-field effect transistors with the use of selective etching and refilling, so the air spacers manufactured by such a process will have the same defects as mentioned.

Therefore, how to avoid the shortcomings of the above-mentioned devices is a technical problem at needs to be resolved.

### SUMMARY OF THE INVENTION

To overcome problems in the prior arts, the present invention provides a semiconductor transistor structure having air spacers with controllable size and shape and the method for making the device.

According to one aspect of the present invention, a transistor structure is provided. The transistor structure includes a substrate, a semiconductor layer disposed on the substrate and a gate layer disposed on the semiconductor layer, wherein the gate layer includes at least one gate having a first height, a first side and a second side opposite to the first side, a first dielectric spacer is disposed at the first side of the at least one gate, a first air spacer having a second height is disposed inside the first dielectric spacer, and the second height is lower than the first height.

According to another aspect of the present invention, a method for making an air spacer in a transistor structure is provided. The method includes steps of: providing a substrate and a semiconductor layer disposed thereon; forming at least one gate on the semiconductor layer, wherein the at least one gate has a first height, a first and a second side opposite to the first side; disposing a first dielectric spacer at the first side; forming a first sacrificial spacer at a specific side of the first dielectric spacer, wherein the first sacrificial spacer has a second height being less than the first height, a predetermined thickness, a top and a corresponding lateral side to the specific side; disposing a porous silicon layer covering the top and the corresponding lateral side; and evaporating the first sacrificial spacer to form the air spacer.

Once the height and the thickness of the air spacer are controllable, the size of the air spacer is controllable, which renders the performance of the circuit consistent when mass-produced and meets industrial needs. Therefore, the present invention has industrial utility.

### BRIEF DESCRIPTION OF THE DRAWINGS

The objectives and advantages of the present invention will become more readily apparent to those ordinarily skilled in the art after reviewing the following detailed descriptions and accompanying drawings.

FIGS. 1-5 are schematic diagrams showing some process steps for manufacturing a transistor structure having an air spacer according to an embodiment of the present invention;

FIGS. 6-9 are schematic diagrams showing some subsequent process steps for fabricating a semiconductor device according to the present invention;

FIGS. 10-14 are schematic diagrams showing some process steps for manufacturing a transistor structure having an air spacer according to another embodiment of the present invention;

FIG. 15 shows a schematic process flow of manufacturing a transistor structure having an air spacer according to the present invention.

### DETAILED DESCRIPTION OF THE PREFERRED EMBODIMENTS

The present invention will now be described more specifically with reference to the following embodiments. It is to be noted that the following descriptions of the preferred embodiments of this invention are presented herein for purpose of illustration and description only; they are not intended to be exhaustive or to be limited to the precise form disclosed.

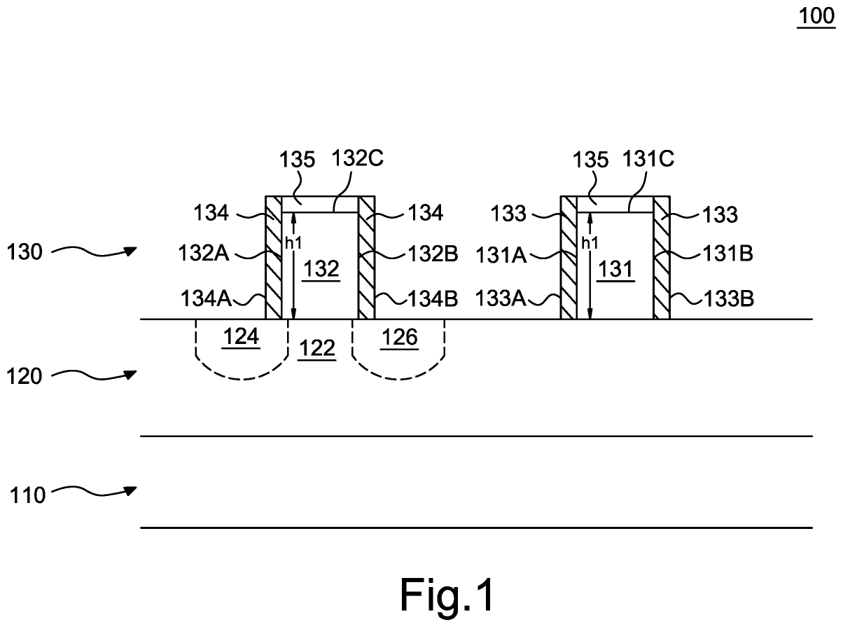

Please refer to FIGS. 1-5, which are cross-sectional side views illustrating some process steps for fabricating a semiconductor transistor structure having an air spacer according to an embodiment of the present invention.

In FIG. 1, the semiconductor device 100 includes a substrate 110, a semiconductor layer 120 disposed on the substrate 110 and a gate layer 130 on the semiconductor layer 120. The semiconductor device 100 may be an integrated circuit (IC) chip, system on chip (SOC), or portion thereof, that may include various passive and active microelectronic devices such as resistors, capacitors, inductors, diodes, metal-oxide semiconductor field effect transistors (MOSFET), complementary metal-oxide semiconductor (CMOS) transistors, bipolar junction transistors (BJT), high power MOS transistors, or other types of transistors. The substrate 110 may be a portion of a semiconductor wafer. For example, the substrate may include silicon. The substrate 110 may alternatively be made of some other suitable elementary semiconductor, such as diamond or germanium; a suitable compound semiconductor, such as silicon carbide, indium arsenide, or indium phosphide; or a suitable alloy semiconductor, such as silicon germanium carbide, gallium arsenic phosphide, or gallium indium phosphide.

The gate layer 130 includes gates 131, 132, each has a predetermined height h₁. In one embodiment, the gates 131, 132 can be formed of filling material such as polysilicon to be replaced by metal material later in a subsequent process step, which is according to the replacement metal gate (RMG) scheme. In other embodiments, any of the gates 131, 132 can be formed of metal materials. In the cross-sectional side view of FIG. 1, the semiconductor layer 120 includes a silicon region 122 underneath the gate 132 and two doped portions 124 and 126 disposed at each side of the silicon region 122, and there is not any doped portion in the silicon region 122. In one embodiment, the gate 131 can be considered as a dummy gate. In another embodiment, there can be a pair of doped portions near the gate 131 but at a perpendicular direction to the cutting line of the cross-sectional side view and thus cannot be shown in FIG. 1. The doped portions 124 and 126 can be used as a drain and a source, which may constitute a fundamental transistor structure with the gate 132.

In the gate layer 130, each of the gates 131, 132 has a left side 131A, 132A, a right side 131B, 132B and a top side 131C, 132C respectively. One may consider the left sides 131A, 132A as the first side and the right sides 131B, 132B as the second sides, and thus for each particular gate, the second side thereof is opposite to the first side. Alternatively, a hard mask 135 is disposed at the top side 131C, 132C of the gates 131, 132. Dielectric spacers 133 and 134 formed of silicon nitride are disposed at both sides of the gates 131, 132. It can be observed from the illustration of FIG. 1 that the height of each of the dielectric spacers 133, 134 is no less than the height h₁ of the gates 131, 132, and the doped portions 124, 126 are adjacent to the left side 132A and the right side 132B of the gate 132 respectively.

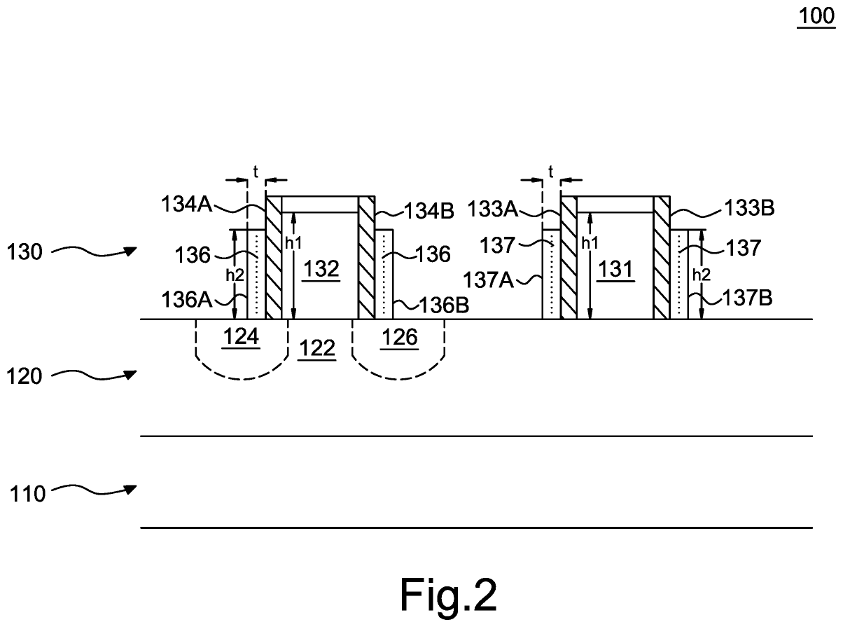

FIG. 2 shows the process step of forming the sacrificial spacers 136, 137 on each of the outer sides of the dielectric spacers 134, 133 respectively. It can be seen that each of the dielectric spacers 134 disposed at the left 132A and the right side 132B of the gate 132 has an outer side 134A, 134B opposite to the gate 132 respectively. Similarly, each of the dielectric spacers 133 disposed at the left 133A and the right side 133B of the gate 131 has an outer side 133A, 133B opposite to the gate 132 respectively.

In an exemplary embodiment, the sacrificial spacers 136, 137 can be formed by applying a deposition process such as chemical vapor deposition (CVD) process to dispose energy removal material such as thermal decomposable material on top of the semiconductor layer 120 and following an etch back process, so as to make each of the sacrificial spacers 136, 137 has a predetermined thickness t and height h2. The height h2 of the sacrificial spacers 136, 137 can be determined by the CVD process. In one embodiment, dry etching with a high selectivity is applied to the film of energy removal material formed after the CVD process, to form the shape of the sacrificial spacers 136, 137. In another embodiment, wet etching is also applicable for the same purpose. It is appreciated by the skilled person in the art that the height h2 of the sacrificial spacers 136, 137 is less than that of the gates 131, 132, and thus the sacrificial spacers 136, 137 may be fully buried by porous silicon material afterwards so the air spacers to be formed can be considered inside the dielectric spacers (not shown) next to the gates 131, 132.

In one embodiment, the energy removal material can include a photonic decomposable material, a thermal decomposable material, and an e-beam decomposable material. In other embodiments, the energy removal material includes an organic compound, a silicon-based CxHy compound, or a thermal decomposable polymer such as, for example P (neopentyl methacrylate-co-ethylene glycol dimethacrylate) copolymer, abbreviated as P (npMAco-EGDA).

Thanks to the maturity of the technology development in the semiconductor industry, the dimension of the elements such as the thickness t and height h2 of the sacrificial spacers 136, 137 can be precisely controlled to a certain degree in terms of accuracy. Therefore, both the size and the shape of the air spacers (not shown in FIG. 2) to be formed near the gates 131, 132 can be well controlled and kept consistent within a wafer or between wafers when mass production is required.

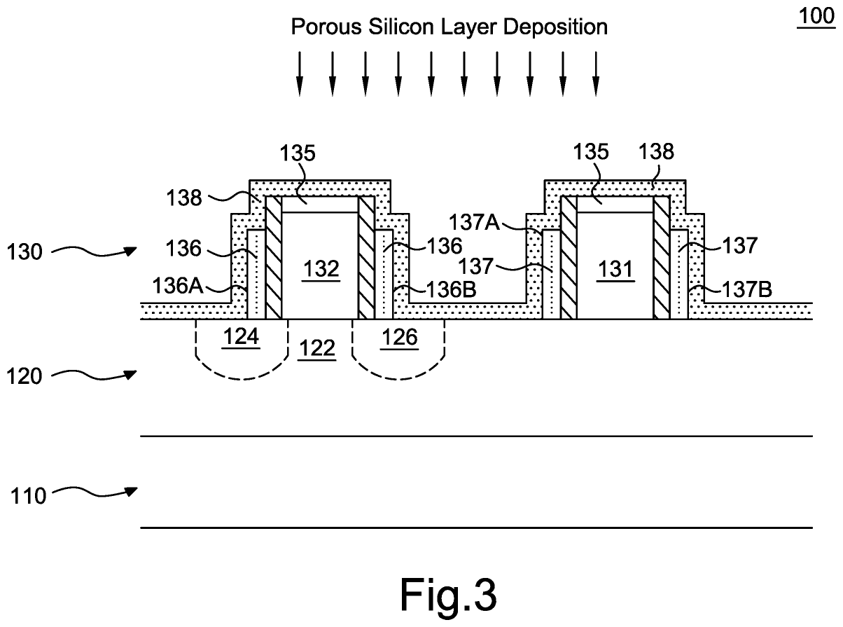

FIG. 3 shows the process step of a porous silicon deposition after the sacrificial spacers 136, 137 in FIG. 2 have been formed. It can be understood from the illustration that the sacrificial spacers 136, 137 each has an outer side 136A, 136B, 137A, 137B respectively. The porous silicon deposition can be implemented by the CVD process or physical vapor deposition (PVD) process. After the deposition is completed, a porous silicon layer 138 covering the top sides 131C, 132C of the gates 131, 132 and the corresponding sides 136A, 136 B, 137A and 137B of the sacrificial spacers 136, 137 respectively. It can be understood from the illustration of FIG. 3 that the porous silicon layer 138 also covers the top of the sacrificial spacers 136, 137, and thus the latter are buried by the former.

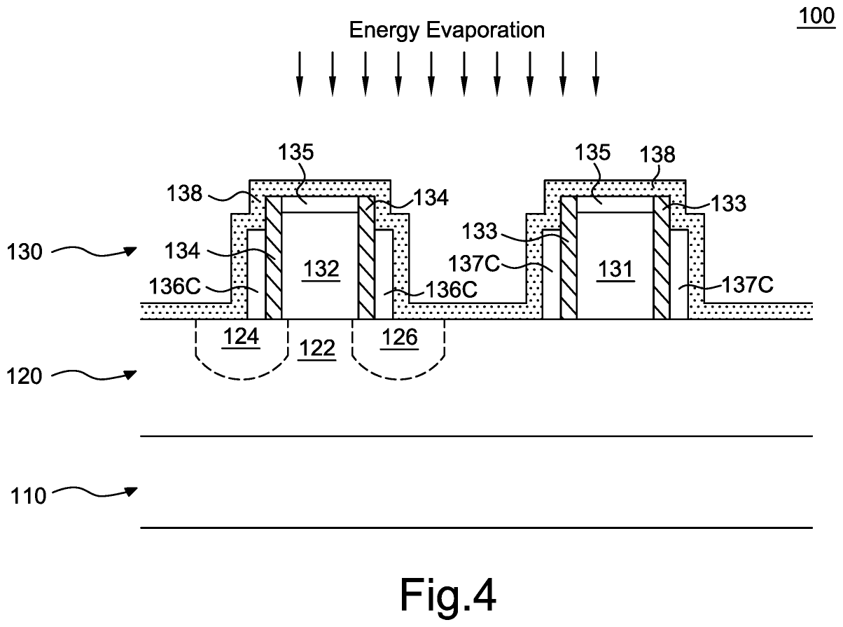

FIG. 4 shows the process step of evaporating the sacrificial spacers 136, 137 formed of energy removal material. The energy removal material of the sacrificial spacers 136, 137 can be decomposable upon being exposed to proper energy such as ultraviolet (UV), X-ray, infrared, visual light, thermal energy, electron-beam (e-beam), or other proper energy sources. For example, one energy removal material is decomposable to e-beam with electron energy ranging between about 100 eV and about 500 KeV.

After a completion of the energy evaporation, the sacrificial spacers 136, 137 can be all evaporated and flow out of the porous silicon layer 138 due to its porous property, and there forms air spacers 136C, 137C having the same shape, i.e. the height h2 and the thickness t2, of the sacrificial spacers 136, 137.

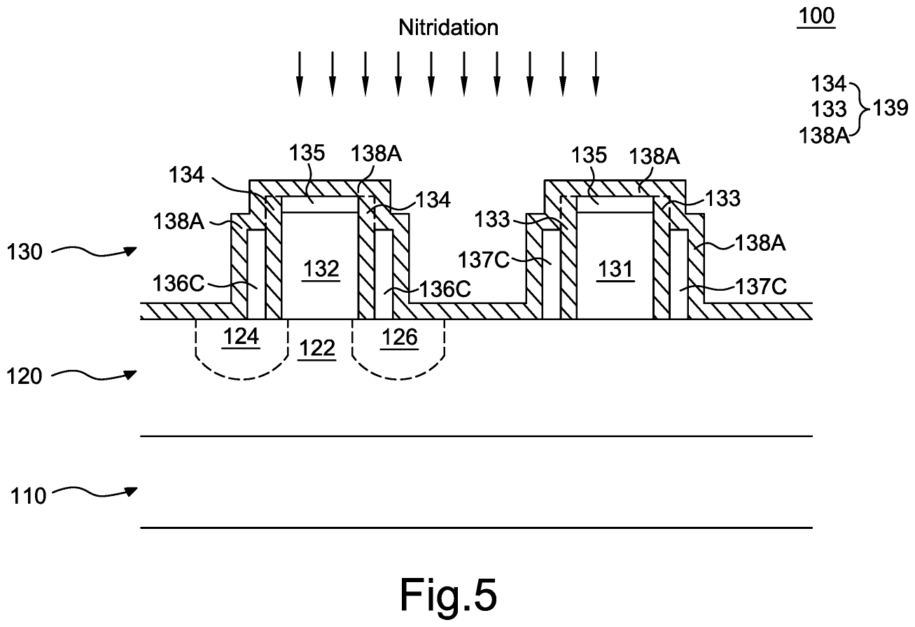

FIG. 5 shows the process of nitridation to the porous silicon layer 138 so as to transform the porous silicon layer 138 into a silicon nitride layer 138A of the same shape. After the nitridation has been done, the dielectric spacers 133, 134 of silicon nitride can be combined with the silicon nitride layer 138A, and the combination at each side of the gates 131, 132 can be considered as dielectric spacers 139 with air spacers 137C, 136C inside respectively. From a different aspect, the skilled person in the art can appreciate that each dielectric spacer 139 includes a porous portion which is formed of silicon nitride or a portion of the porous silicon nitride layer 138A.

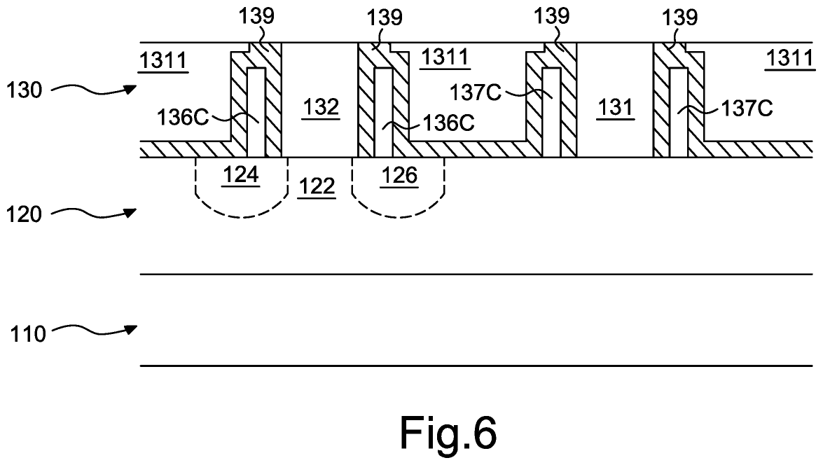

Please refer to FIGS. 6-9, which are cross-sectional side views illustrating some subsequent process steps for fabricating a semiconductor device having an air spacer according to the present invention, after the process steps illustrated in FIGS. 1-5 has been performed.

In FIG. 6, some filling material 1311 such as silicon oxide or the like are disposed on the gate layer 130 before performing a chemical mechanical planarization (CMP) process to remove the portions of the silicon nitride layer 138A on the top side 131C, 132C of the gate 131, 132 and the hard masks 135 if necessary. After the CMP process, it appears in the illustration of FIG. 6 that the gates 131, 132 are exposed to the top. According to one embodiment of the present invention, for the RMG scheme, the original gate material can be removed by an etching process and suitable conductive metals such as aluminum, platinum, gold, tungsten, titanium, or any combination thereof may be deposited by a suitable deposition process, for example, CVD, PECVD, PVD, plating or sputtering. In a different embodiment, the gates 131, 132 are formed of pre-arranged gate material so there is no need to do the material replacement procedure.

Again in FIG. 6, it can be seen that the dielectric spacers 139 with the air spacers 137C, 136C thereinside are formed at both sides of the gates 131, 132 respectively. Comparing the illustrations in FIG. 2 and FIG. 6, it is appreciated by the skilled person in the art that, due to the fact that the height h2 of the sacrificial spacers 136, 137 is less than the height h1 of the gates 131, 132, the air spacers 136C, 137C can be fully included or buried inside the dielectric spacers 139 after the CMP process, which makes the present invention advantageous over the prior art technologies.

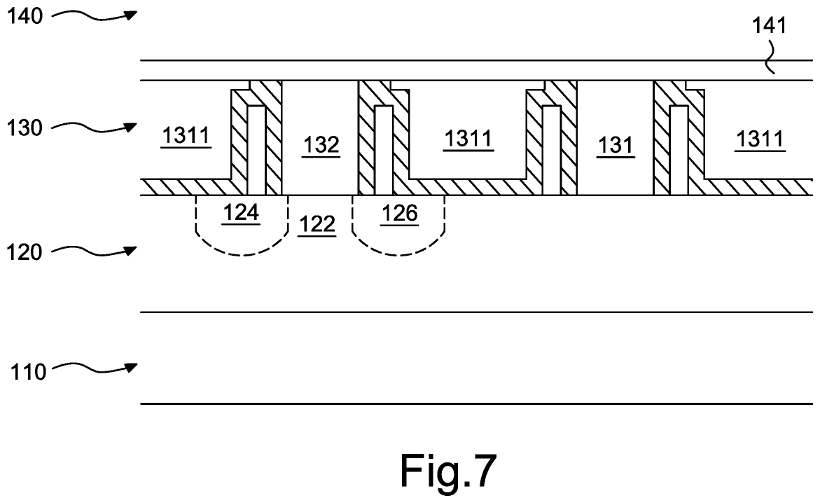

FIG. 7 shows the subsequent process step after that of FIG. 6. In FIG. 7, a dielectric layer 141, mainly formed of dielectric material such as silicon nitride or the like, is disposed on top of the gate layer 130. This layer can be considered as a foundation of the circuit layer 140.

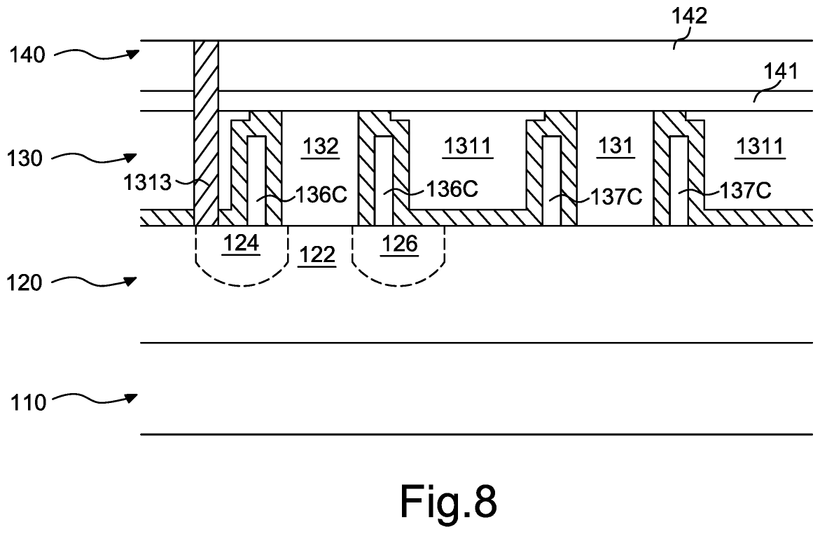

FIG. 8 shows the subsequent process step after that of FIG. 7. In FIG. 8, a layer of TEOS oxide 142 is disposed on the dielectric layer 141, and at least of a metal contact 1313 is formed by etching all the way through the bottom of the gate layer 130 to the doped portion 124 and filling the metal material with a suitable deposition process. The metal contact 1313 shown in FIG. 8 can be considered as a source contact of the doped portion 124 if the latter is functioning as a source of a transistor.

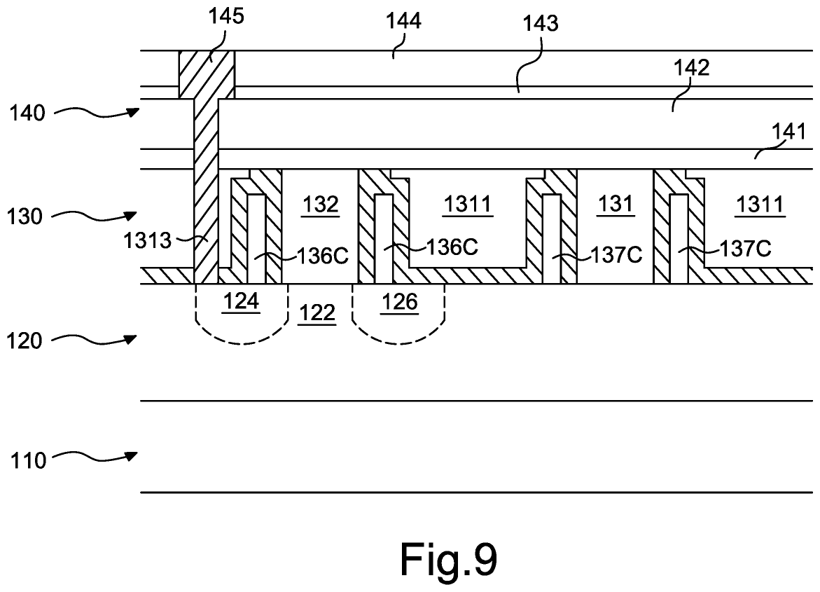

FIG. 9 schematics an exemplary semiconductor device with the transistor structure based on the semiconductor device 100 as shown in FIG. 5. In FIG. 9, an additional dielectric layer 143 is disposed on the layer of TEOS oxide 142, a passivation layer 144 is formed on the additional dielectric layer 143, and an outer contact 145 is disposed on top of the metal contact 1313. Electronic signals can be transmitted through the outer contact 145 to the source or drain of the transistor underneath.

It is appreciated by the skilled person in the art that, the dielectric space 139 with the air spacer 136C is disposed between the gate 132 and the metal contact 1313, and therefore the parasitic capacitance effect can be significantly reduced. Furthermore, such a reduction for the parasitic capacitance effect can be consistent due to the size of the air spacers are well controlled in the present invention.

Notably, there is one metal contact 1313 shown in the illustrations of FIGS. 8 and 9 for the need of briefly introducing the concept of the present invention. In different embodiments, there could be some other metal contacts (not shown) disposed on another doped portion such as the doped portion 126, and thus there will be another dielectric spacers 139 with the air spacer 136C inside disposed between the gate 132 and the other metal contact (not shown) connecting to the doped portion 126 so as to reduce the parasitic capacitance effect.

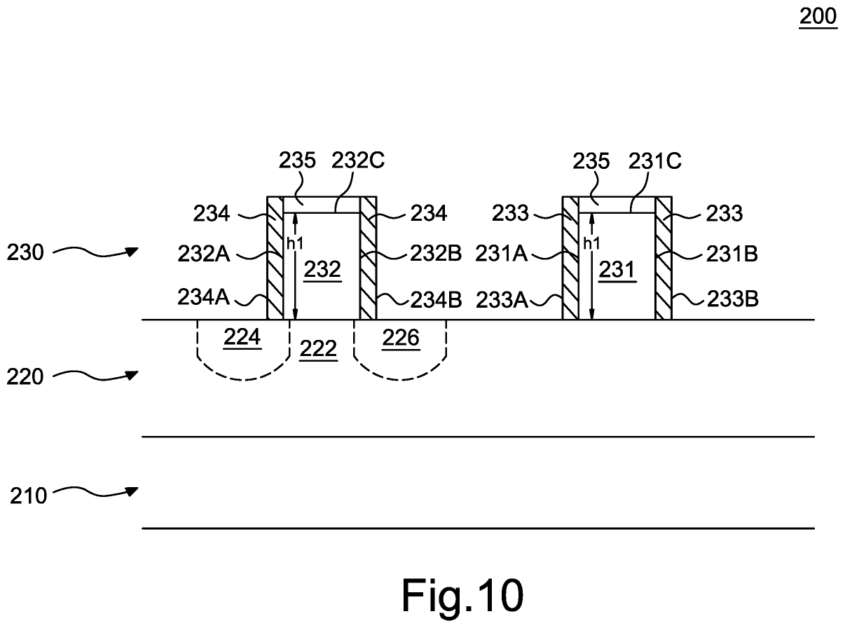

Please refer to FIGS. 10-14, which are cross-sectional side views illustrating some process steps for fabricating a semiconductor transistor structure having an air spacer according to another embodiment of the present invention.

In FIG. 10, the semiconductor device 200 includes a substrate 210, a semiconductor layer 220 disposed on the substrate 210 and a gate layer 230 on the semiconductor layer 220. The substrate 210 may be a portion of a semiconductor wafer. Details of the semiconductor materials available for this embodiment is similar to that in FIGS. 1-5, so there is no need to repeat.

The gate layer 230 includes gates 231, 232, each has a predetermined height h₁. In one embodiment, the gates 231, 232 can be formed of filling material such as polysilicon to be replaced by metal material later in a subsequent process step, which is according to the replacement metal gate (RMG) scheme. In other embodiments, any of the gates 231, 232 can be formed of metal materials.

In the cross-sectional side view of FIG. 10, the semiconductor layer 220 includes a silicon region 222 underneath the gate 232 and two doped portions 224 and 226 disposed at each side of the silicon region 222, and there is not any doped portion in the silicon region 222. In one embodiment, the gate 231 can be considered as a dummy gate. In another embodiment, there can be a pair of doped portions near the gate 231 but at a perpendicular direction to the cutting line of the cross-sectional side view and thus cannot be shown in FIG. 10. The doped portions 224 and 226 can be used as a drain and a source, which may constitute a fundamental transistor structure with the gate 232.

In the gate layer 230, each of the gates 231, 232 has a left side 231A, 232A, a right side 231B, 232B and a top side 231C, 232C respectively. One may consider the left sides 231A, 232A as the first side and the right sides 231B, 232B as the second sides, and thus for each particular gate, the second side thereof is opposite to the first side. Alternatively, a hard mask 235 is disposed at the top side 231C, 232C of the gates 231, 232. Dielectric spacers 233 and 234 formed of silicon oxide or silicon dioxide are disposed at both sides of the gates 231, 232. It can be observed from the illustration of FIG. 10 that the height of each of the dielectric spacers 233, 234 is no less than the height h₁ of the gates 231, 232, and the doped portions 224, 226 are adjacent to the left side 232A and the right side 232B of the gate 232 respectively.

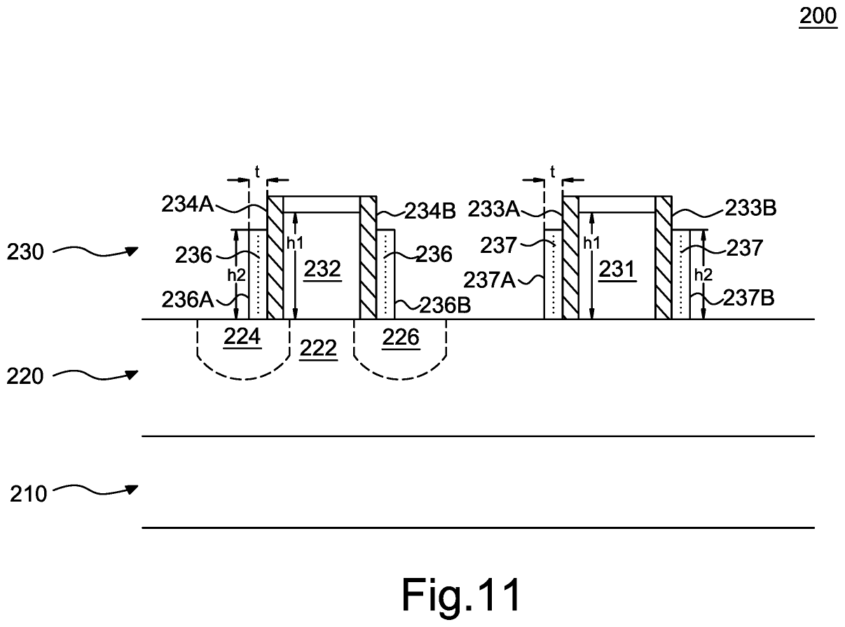

FIG. 11 shows the process step of forming the sacrificial spacers 236, 237 on each of the outer sides of the dielectric spacers 234, 233 respectively. It is appreciated that each of the dielectric spacers 234 disposed at the left 232A and the right side 232B of the gate 132 has an outer side 234A, 234B opposite to the gate 232 respectively. Similarly, each of the dielectric spacers 233 disposed at the left 233A and the right side 233B of the gate 231 has an outer side 233A, 233B opposite to the gate 232 respectively. The process employed to form the sacrificial spacers 236, 237 can be similar to that of the previous one, so as to make each of the sacrificial spacers 236, 237 has a predetermined thickness t and height h2, which can be well controlled. The choices of the materials for the sacrificial spacers 236, 237 are the same as those for the sacrificial spacers 136, 137 in the previous embodiment, so there is no need to repeat.

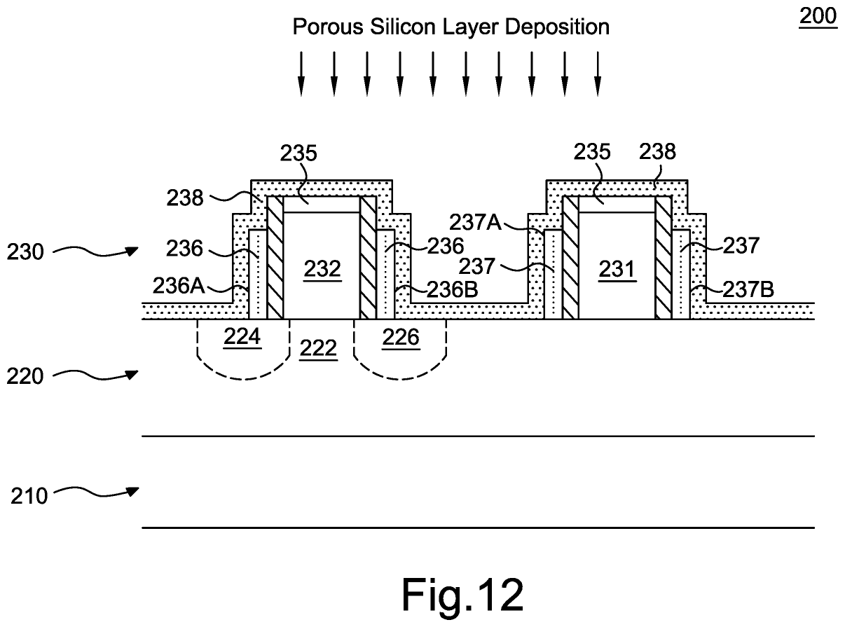

FIG. 12 shows the process step of a porous silicon deposition after the sacrificial spacers 236, 237 in FIG. 11 have been formed. It can be understood from the illustration that the sacrificial spacers 236, 237 each has an outer side 236A, 236B, 237A, 237B respectively. The porous silicon deposition can be implemented by the CVD process or physical vapor deposition (PVD) process. After the deposition is completed, a porous silicon layer 238 covering the top sides 231C, 232C of the gates 231, 232 and the corresponding sides 236A, 236 B, 237A and 237B of the sacrificial spacers 236, 237 respectively. It can be understood from the illustration of FIG. 12 that the porous silicon layer 238 also covers the top of the sacrificial spacers 236, 237, and thus the latter are buried by the former.

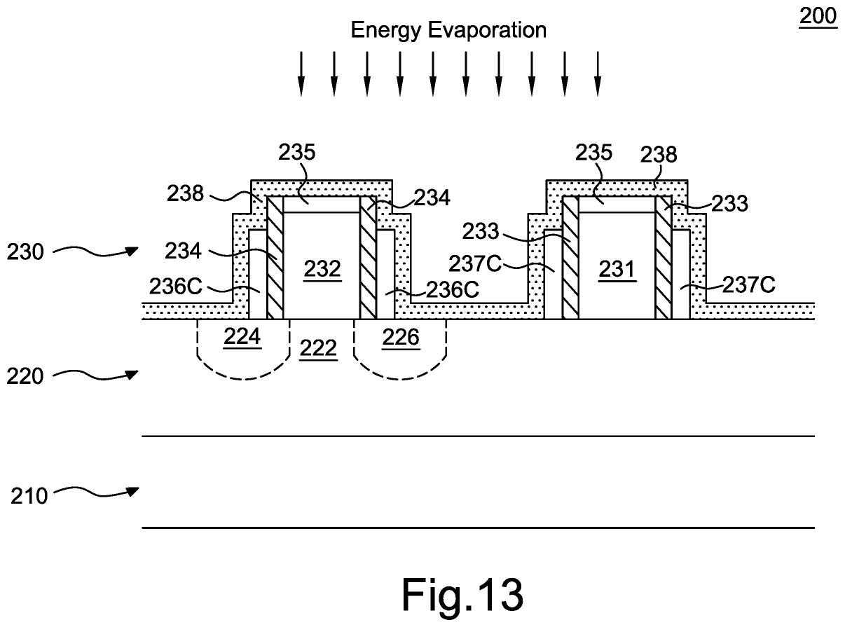

FIG. 13 shows the process step of evaporating the sacrificial spacers 236, 237 formed of energy removal material. The energy removal material of the sacrificial spacers 236, 237 can be decomposable upon being exposed to proper energy such as ultraviolet (UV), X-ray, infrared, visual light, thermal energy, electron-beam (e-beam), or other proper energy sources. For example, one energy removal material is decomposable to e-beam with electron energy ranging between about 100 eV and about 500 KeV.

After a completion of the energy evaporation, the sacrificial spacers 236, 237 can be all evaporated and flow out of the porous silicon layer 238 due to its porous property, and there forms air spacers 236C, 237C having the same shape, i.e. the height h2 and the thickness t2, of the sacrificial spacers 236, 237.

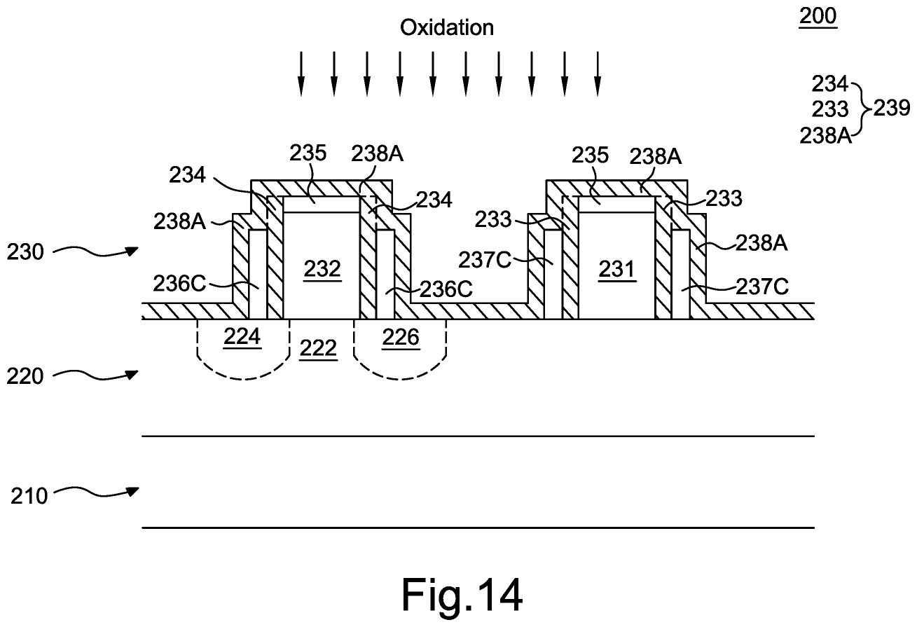

FIG. 14 shows the process of oxidation to the porous silicon layer 238 so as to transform the porous silicon layer 238 into a silicon oxide layer 238A of the same shape. After the nitridation has been done, the dielectric spacers 233, 234 of silicon oxide can be combined with the silicon oxide layer 238A, and the combination at each side of the gates 231, 232 can be considered as dielectric spacers 239 with air spacers 237C, 236C inside respectively. From a different aspect, the skilled person in the art can appreciate that each dielectric spacer 239 includes a porous portion which is formed of silicon oxide or a portion of the porous silicon oxide layer 238A. In some embodiments, the porous silicon oxide layer 238A may include a silicon dioxide material.

The subsequent process steps for fabricating a semiconductor device having an air spacer according to the present invention, after the process steps illustrated in FIGS. 10-14 has been performed, can be similar to those as shown in FIGS. 6-9, so there is no need to repeat.

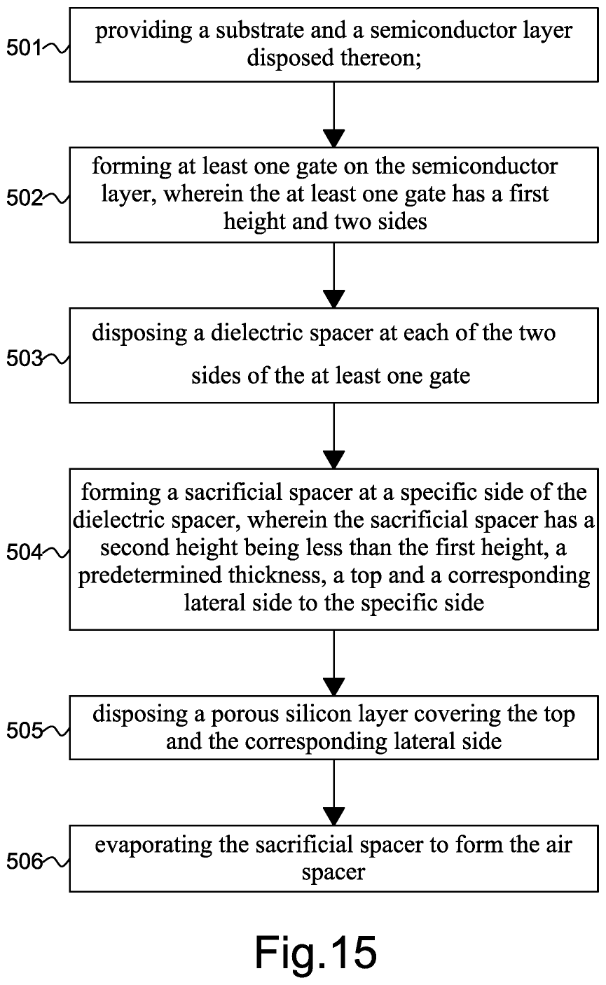

FIG. 15 shows a schematic process flow of manufacturing a transistor structure having an air spacer according to the present invention. The process flow includes the steps of: providing a substrate and a semiconductor layer disposed thereon (Step 501); forming at least one gate on the semiconductor layer, wherein the at least one gate has a first height and two sides (Step 502), wherein the two sides are a first and a second side opposite to the first side; disposing a first dielectric spacer at the first side and a second dielectric spacer at the second side (Step 503); forming a first and a second sacrificial spacers at a specific side of the first and the second dielectric spacer respectively, wherein the sacrificial spacers each has a second height being less than the first height, a predetermined thickness, a top and a corresponding lateral side to the specific side (Step 504); disposing a porous silicon layer covering the top and the corresponding lateral sides (Step 505); and evaporating at least the first sacrificial spacer to form the air spacer (Step 506).

The skilled person in the art can understand that some subsequent process steps as shown in FIGS. 6-9 can be further performed after the Step 506 in FIG. 15 to form a completed gate layer including a transistor device on top of the semiconductor layer and a circuit layer on the gate layer, so there is no need to repeat.

While the invention has been described in terms of what is presently considered to be the most practical and preferred Embodiments, it is to be understood that the invention need not be limited to the disclosed Embodiments. On the contrary, it is intended to cover various modifications and similar arrangements included within the spirit and scope of the appended claims, which are to be accorded with the broadest interpretation so as to encompass all such modifications and similar structures.

1. A transistor structure comprising:
a substrate;
a semiconductor layer disposed on the substrate; and
a gate layer disposed on the semiconductor layer, wherein:
the gate layer includes at least one gate having a first height, a first side and a second side opposite to the first side,
a first dielectric spacer is disposed at the first side of the at least one gate,
a first air spacer having a second height is disposed inside the first dielectric spacer, wherein the second height is lower than the first height.

2. The transistor structure as claimed in claim 1, wherein the at least one gate is formed by a gate material being one of a metal and a polysilicon, and the at least one gate is one of a dummy gate and a transistor gate.

3. The transistor structure as claimed in claim 1, further including a second dielectric spacer disposed at the second side of the at least one gate and a second air spacer disposed inside the second dielectric spacer, wherein the second air spacer has the second height.

4. The transistor structure as claimed in claim 3, further comprising a third and a fourth dielectric spacers disposed adjacent to the first and the second sides of the at least one gate respectively.

5. The transistor structure as claimed in claim 3, wherein the first and the second dielectric spacers each includes a silicon nitride, a silicon oxide or a silicon dioxide, and each includes a porous portion.

6. The transistor structure as claimed in claim 1, wherein the semiconductor layer further includes a source portion disposed adjacent to the first side of the at least one gate and a drain portion disposed adjacent to the second side of the at least one gate.

7. The transistor structure as claimed in claim 6, wherein the gate layer further includes a source contact being connected to the source portion in the semiconductor layer.

8. The transistor structure as claimed in claim 7, wherein the first air spacer is disposed between the source contact and the at least one gate.

9. The transistor structure as claimed in claim 7, further comprising a circuit layer disposed on the gate layer, and including a top surface and a contact portion exposed to the top surface, wherein the source contact is connected to the contact portion.

10. The transistor structure as claimed in claim 6, wherein the gate layer further includes a drain contact being connected to the drain portion in the semiconductor layer.

11. The transistor structure as claimed in claim 10, wherein the second air spacer is disposed between the drain contact and the at least one gate.

12. A method for making an air spacer in a transistor structure, comprising steps of:
providing a substrate and a semiconductor layer disposed thereon;
forming at least one gate on the semiconductor layer, wherein the at least one gate has a first height, a first and a second side opposite to the first side;
disposing a first dielectric spacer at the first side;
forming a first sacrificial spacer at a specific side of the first dielectric spacer, wherein the first sacrificial spacer has a second height being less than the first height, a predetermined thickness, a top and a corresponding lateral side to the specific side;
disposing a porous silicon layer covering the top and the corresponding lateral side; and
evaporating the first sacrificial spacer to form the air spacer.

13. The method as claimed in claim 12, wherein the at least one gate is formed by a gate material being one of a metal and a polysilicon, and the at least one gate is one of a dummy gate and a transistor gate.

14. The method as claimed in claim 12, wherein the step of disposing a first dielectric spacer at the first side further includes a sub-step of disposing a second dielectric spacer at the second side simultaneously.

15. The method as claimed in claim 14, wherein the step of forming the first sacrificial spacer at a specific side of the first dielectric spacer further includes a sub-step of disposing a second sacrificial spacer at another specific side of the second dielectric spacer simultaneously, the first and the second sacrificial spacers are formed of an energy removable material, and the step of evaporating the first sacrificial spacer to form the air spacer is performed by applying an energy to the first sacrificial spacer.

16. The method as claimed in claim 15, wherein each of the first and the second dielectric spacers includes a silicon nitride, and the method further includes a step of:
performing a nitridation to transform the porous silicon layer to a silicon nitride layer.

17. The method as claimed in claim 15, wherein the dielectric spacer includes a silicon oxide, and the method further includes a step of:
performing an oxidation to transform the porous silicon layer to a silicon oxide layer.

18. The method as claimed in claim 12, wherein the semiconductor layer further includes a source portion disposed adjacent to the first side of the at least one gate, and the method further includes a step of:
forming a source contact on the source portion.

19. The method as claimed in claim 12, wherein the semiconductor layer further includes a drain portion disposed adjacent to the second side of the at least one gate, and the method further includes a step of:
forming a drain contact on the drain portion.

20. The method as claimed in claim 12, wherein the at least one gate, the first dielectric spacer, the first sacrificial spacer and the porous silicon layer constitute a gate layer, and the method further including a step of:
forming a circuit layer on the gate layer.
